(19) United States
(12) Patent Application Publication
(10) Pub. No.: US 2009/0236672 A1
(43) Pub. Date: Sep. 24, 2009

(54) SEMICONDUCTOR DEVICE

(75) Inventors: Hiromitsu HARASHIMA, Tokyo (JP); Toshifumi Minami, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: Kabushiki Kaisha Toshiba, Tokyo (JP)

(21) Appl. No.: 12/369,815

(22) Filed: Feb. 12, 2009

(30) Foreign Application Priority Data
Mar. 24, 2008 (JP) 2008-075610

(51) Int. Cl. H01L 27/088

(52) U.S. Cl. 257/390; 257/E27.06

(57) ABSTRACT

A semiconductor device includes a plurality of metal-insulator-semiconductor (MIS) transistors formed on a surface portion of a semiconductor substrate; and an isolation region isolating each of element regions of the MIS transistors, the isolation region including a first isolation region formed with a coating type insulating film embedded in a first trench, the first trench surrounding each of the element regions of the MIS transistors, and a second isolation region formed with a coating type insulating film embedded in a second trench, the second trench surrounding at least one of the first isolation regions with a predetermined distance from each of the first isolation regions, wherein the semiconductor substrate exists between the first isolation region and the second isolation region.

### CROSS REFERENCE TO RELATED APPLICATIONS

This application is based upon and claims the benefit of priority from the prior Japanese Patent Application No. 2008-75610, filed on Mar. 24, 2008, the entire contents of which are incorporated herein by reference.

### BACKGROUND OF THE INVENTION

1. Field of the Invention

The present invention relates to a semiconductor device.

2. Related Art

In recent years, as a material to isolate between elements in a memory cell array, hereinafter referred to as a cell array, in which miniaturization has been propelled, as disclosed, for example, in Japanese Patent Application Publication No. JP-A 2006-339446 (KOKAI), an insulating film of coating type has been widely used because of its high embedding ability in a trench of a shallow trench isolation (STI).

Furthermore, by forming the cell array and a circuit which controls the cell array, hereinafter referred to as a peripheral circuit, at the same time, the number of processes can be substantially reduced. For this reason, the coating type insulation film has also been used as an embedding material for STI trenches for the entire peripheral circuits.

However, in general, since organic materials are used for the coating type insulating film which requires heat treatment at a high temperature to cure after embedding by coating, there appears an extremely strong tensile stress when formed.

Because of this stress, in a peripheral circuit portion where element density is low, a pit of crystal defect is made in a semiconductor substrate where elements such as transistors are formed, thereby causing the peripheral circuit to malfunction.

An NAND flash memory employs a method of applying a very high voltage, e.g. 15 to 30 V, to a memory cell to achieve an FN tunneling phenomenon to write and erase data. Therefore, in order to control such high voltages, a peripheral circuit with a metal-insulator-semiconductor (MIS) transistor of a high breakdown voltage, hereinafter simply referred to as a high voltage MIS transistor, becomes essential. In the high voltage MIS transistor, because of the characteristics of transferring such high voltages, its channel impurity concentration requires to be controlled at a low concentration of, for example, about 1E16 cm⁻³.

However, the organic materials are used for the coating type insulating film. Therefore, due to the material of the film, it is impossible to completely remove carbon that is a contaminant, thus residual carbon remains. In the high voltage MIS transistor of the low channel concentration, the carbon in a field oxide film acts to negate donor ions in the vicinity of the channel of the high voltage MIS transistor, thereby causing variations in threshold value Vth and such.

As described above, the coating type insulating film used for fabricating miniaturized cell arrays has significant adverse effects on the high voltage MIS transistors in the peripheral circuit, thus there is a great difficulty in performing element isolation of the cell array and the high voltage MIS transistors in the peripheral circuit at the same time.

Therefore, in order to stabilize the characteristics of the peripheral circuit where the high voltage MIS transistors lie, it has been necessary to fabricate the cell array and its peripheral circuit in separate steps, thereby substantially increasing the number of fabrication steps.

In addition, in the NAND flash memory, as one of the peripheral circuits which require a high breakdown voltage for controlling the cell array, there is a row decoder circuit in which high voltage MIS transistors are disposed in arrays. However, because of the influence of the carbon contained in the coating type insulating film as described above, making the width W of the transistor smaller accelerates an inverse narrow channel effect which lowers the threshold value Vth and aggravates a punch-through of the high voltage MIS transistors.

Meanwhile, in element isolation of the row decoder circuit, a chip area can be made smaller by making its density higher. However, when the distance between high voltage MIS transistors is made small, the volume of the coating type insulating film is affected, making a reverse field effect larger between a transistor in which a voltage is applied to a gate electrode and an adjacent transistor in which no voltage is applied. Thus, a leak current between those high voltage MIS transistors is increased. Consequently, it is required to extend the distance between the high voltage MIS transistors, thus it has been impossible to reduce the area of the semiconductor circuit.

### SUMMARY OF THE INVENTION

A semiconductor device according to an embodiment of the present invention includes:

a plurality of metal-insulator-semiconductor (MIS) transistors formed on a surface portion of a semiconductor substrate; and

an isolation region isolating each of element regions of the MIS transistors, the isolation region including a first isolation region formed with a coating type insulating film embedded in a first trench, the first trench surrounding each of the element regions of the MIS transistors, and a second isolation region formed with a coating type insulating film embedded in a second trench, the second trench surrounding at least one of the first isolation regions with a predetermined distance from each of the first isolation regions, wherein

the semiconductor substrate exists between the first isolation region and the second isolation region.

### BRIEF DESCRIPTION OF THE DRAWINGS

FIG. 1 shows a plan view of a structure of a group of low voltage MIS transistors in a semiconductor device of a first embodiment of the present invention;

FIGS. 2 and 3 show respective cross-sectional views taken along the lines A-A and B-B shown in FIG. 1;

FIG. 4 shows a plan view of a structure of a group of low voltage MIS transistors in a semiconductor device of a first comparative example;

FIGS. 5 and 6 show respective cross-sectional views taken along the lines A-A and B-B shown in FIG. 4;

FIG. 7 shows a plan view of a structure of a group of high voltage MIS transistors in a semiconductor device of a second embodiment of the present invention;

FIGS. 8 and 9 show respective cross-sectional views taken along the lines A-A and B-B shown in FIG. 7;

FIGS. 10 and 11 show respective cross-sectional views taken along the lines A-A and B-B shown in FIG. 7;

FIG. 12 shows a plan view of a structure of a group of high voltage MIS transistors in a semiconductor device of a second comparative example;

FIGS. 13 and 14 show respective cross-sectional views taken along the lines A-A and B-B shown in FIG. 12;

FIG. 15 shows a plan view of a structure of a group of high voltage MIS transistors included in a row decoder circuit of a semiconductor device of a third embodiment of the present invention;

FIGS. 16 to 18 show respective cross-sectional views taken along the lines A-A, B-B and C-C shown in FIG. 15;

FIG. 19 shows a plan view of a structure of a group of high voltage MIS transistors included in a row decoder circuit of a semiconductor device of a third comparative example; and

FIGS. 20 to 22 show respective cross-sectional views taken along the lines A-A, B-B and C-C shown in FIG. 19.

### DETAILED DESCRIPTION OF THE INVENTION

Embodiments according to the present invention will now be explained with reference to the accompanying drawings.

### First Embodiment

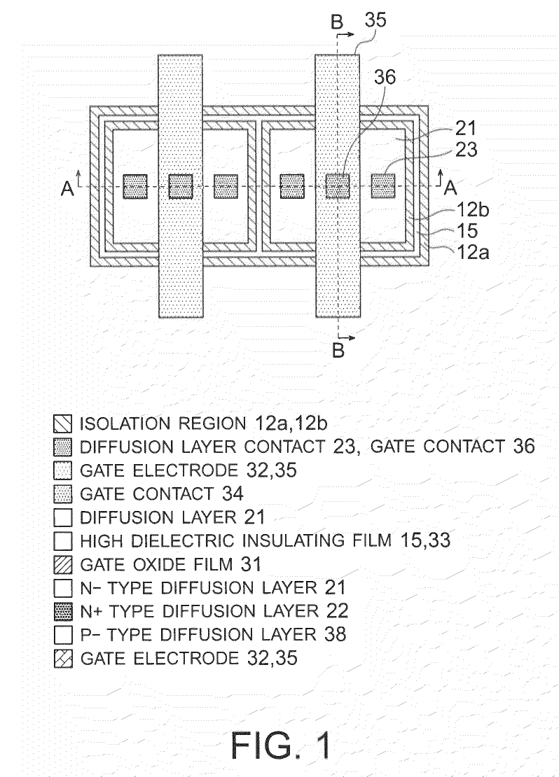

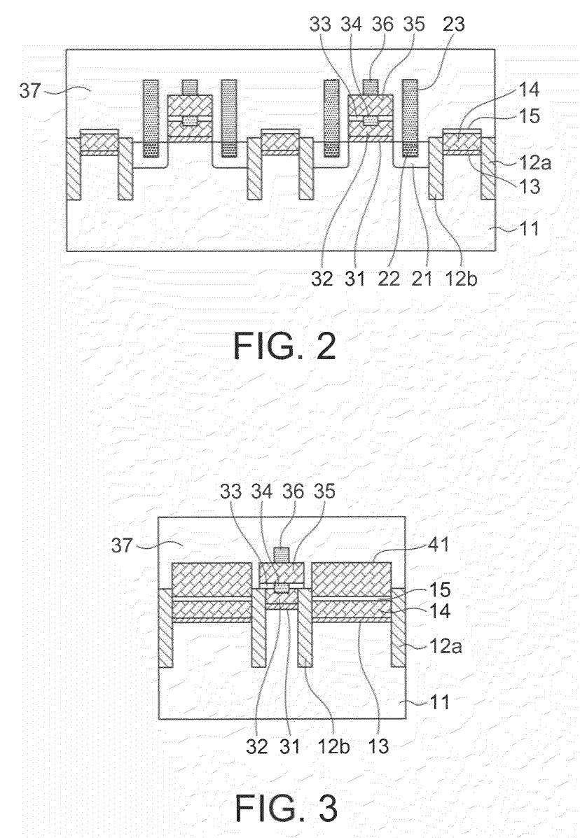

FIG. 1 shows a plan view of a structure of a group of low voltage MIS transistors in a semiconductor device of a first embodiment of the present invention. Further, FIGS. 2 and 3 show respective cross-sectional views taken along the lines A-A and B-B shown in FIG. 1. Note that the low voltage MIS transistor is a transistor driven by a low voltage of, e.g. 2.5 V, in such circuits as a logic circuit for generating signals and a sense amplifier which are parts of the peripheral circuits of a non-volatile semiconductor memory device such as an NAND flash memory.

As shown in FIGS. 1 and 2, on an upper surface portion of a P type semiconductor substrate 11, two pieces of low voltage MIS transistors are disposed. In each of N⁻ type diffusion layers 21 of the MIS transistors, a gate electrode 35 is provided in a vertical direction near the center of the drawing and, on the gate electrode 35, a gate contact 36 is provided. On the left and right sides of the gate electrode 35 in the diffusion layer 21, source/drain are disposed and, diffusion layer contacts 23 are provided on respective surfaces of the source/drain via N⁺ type diffusion layers 22.

So as to surround the circumference of the diffusion layer 21 of each of the MIS transistors, an isolation region 12b is formed where a coating type insulating film composed of a polysilazane film and such is embedded in an STI trench. Outside the isolation region 12b for the MIS transistor, a dummy element region is provided so as to surround the isolation region 12b. On the dummy element region, a later described high dielectric insulating film 15 and such are formed. Further, outside the dummy element regions for the MIS transistors, so as to surround the dummy element regions, an isolation region 12a is provided where a coating type insulating film composed of a polysilazane film and such is embedded in an STI trench. Note that the isolation region 12a is not provided in between the diffusion layers 21 of the adjacent MIS transistors, but is formed so as to surround two MIS transistors.

In FIG. 2, in a gate electrode region, a tunnel insulating film, i.e. a gate oxide film, 31 composed of a silicon oxide film and such having a film thickness of, e.g. 5 to 8 nm; a floating gate electrode 32 composed of polycrystalline silicon and such; an interelectrode insulating film 33 composed of a high dielectric insulating film and such; a control gate electrode 35 composed of a silicide film or polycrystalline silicon and such; and a gate contact 34 where polycrystalline silicon and such are embedded in an opening opened in the interelectrode insulating film 33 so as to short-circuit the floating gate electrode 32 with the control gate electrode 35 are formed on the semiconductor substrate 11.

Furthermore, in the dummy element region in between the isolation regions 12b and 12a described above, a dummy element is formed on the semiconductor substrate 11. In the dummy element, an insulating film 13 composed of a silicon oxide film and such similar to the tunnel insulating film 31; a conductive film 14 composed of polycrystalline silicon and such similar to the floating gate electrode 32; and a high dielectric insulating film 15 similar to the interelectrode insulating film 33 and such are formed is formed.

Note that, as long as the semiconductor substrate 11 lies in between the isolation regions 12b and 12a, it is not necessarily required for such films 13 to 15 to be formed. However, the films 13 to 15 are formed by sharing fabricating steps for forming the gate electrode.

In FIG. 3, a conductive film 41 is formed on the high dielectric insulating film 15 in the dummy element region. Although such film 41 is not necessarily required, the conductive film 41 similar to the control gate electrode 35 is formed by sharing the fabricating steps for the gate electrode.

By the isolation structure thus described, the volume of the coating type insulating films embedded in the STI trenches of the whole isolation regions surrounded by the isolation regions 12a and 12b can be reduced. Although polysilazane, for example, is used for the coating type insulating film in the STI trenches, the tensile stress is reduced by the reduced volume thereof. Consequently, when forming the isolation regions with the coating type insulating film, the tensile stress which causes the pit of crystal defect can be alleviated for the peripheral circuit portion of the semiconductor substrate where element density is low, thereby preventing the peripheral circuit from malfunctioning. In addition, this structure prevents the characteristics of the transistor from being influenced and eliminates the need of fabricating the cell array and the peripheral circuit in separate steps, thereby preventing the number of fabricating steps from increasing.

In the first embodiment, for the two pieces of adjacent MIS transistors, the isolation region 12a is provided so as to surround the isolation regions 12b which are provided so as to surround each of the diffusion layers 21.

However, it is not necessarily required to define a unit with two pieces of the MIS transistors as such, and the isolation region 12a may be provided individually for each piece of the MIS transistors or may be provided so as to surround three or more pieces of the MIS transistors.

### FIRST COMPARATIVE EXAMPLE

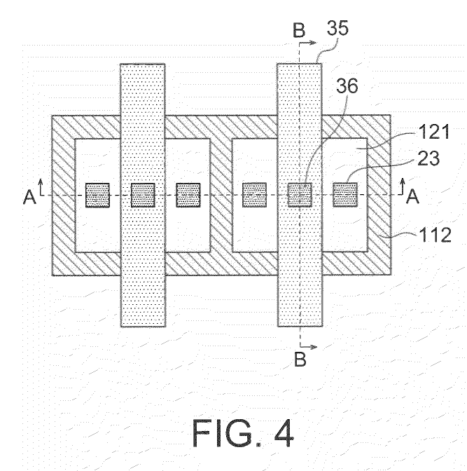

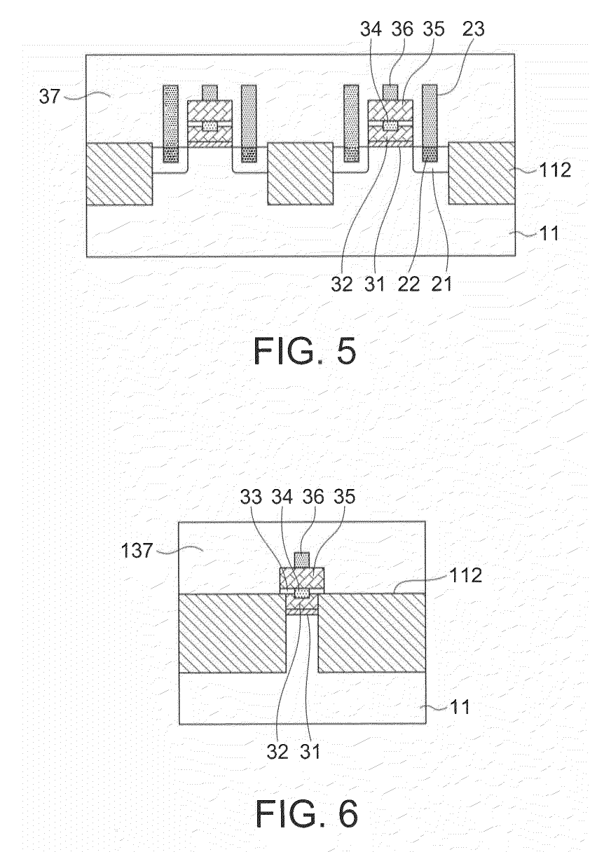

FIG. 4 shows a plan view of a structure of a group of low voltage MIS transistors in a semiconductor device of a first comparative example. Further, FIGS. 5 and 6 show respective cross-sectional views taken along the lines A-A and B-B shown in FIG. 4.

In comparison with the first embodiment described above, the structure of the isolation region differs. In the first embodiment, the isolation region 12b surrounds the N⁻ type diffusion layer 21 of each of the transistors. The isolation region 12a is further provided on the circumference of the isolation region 12b. The dummy element region is provided between the isolation regions 12a and 12b.

On the contrary, in the first comparative example, an STI trench is formed in the entire isolation region. The STI trench is embedded with a coating type insulating film composed of a polysilazane film and such. An isolation region 112 is provided by the STI trench and the coating type insulating film. Note that the volume of the isolation region 12b, the dummy element region and the isolation region 12a, i.e. an area in the plan view, of the first embodiment and the volume of the isolation region 112 of the first comparative example are identical. The other constituent elements of the same are given with the same numerals, and their descriptions are omitted.

In the first comparative example, the entire STI trench is embedded with the coating type insulating film which constitutes the isolation region 112, thus its volume is larger than that of the first embodiment. Consequently, the tensile stress by thermal shrinkage is more strongly exerted, thus the pit of crystal defect appears in the semiconductor substrate which causes the circuit to malfunction.

### Second Embodiment

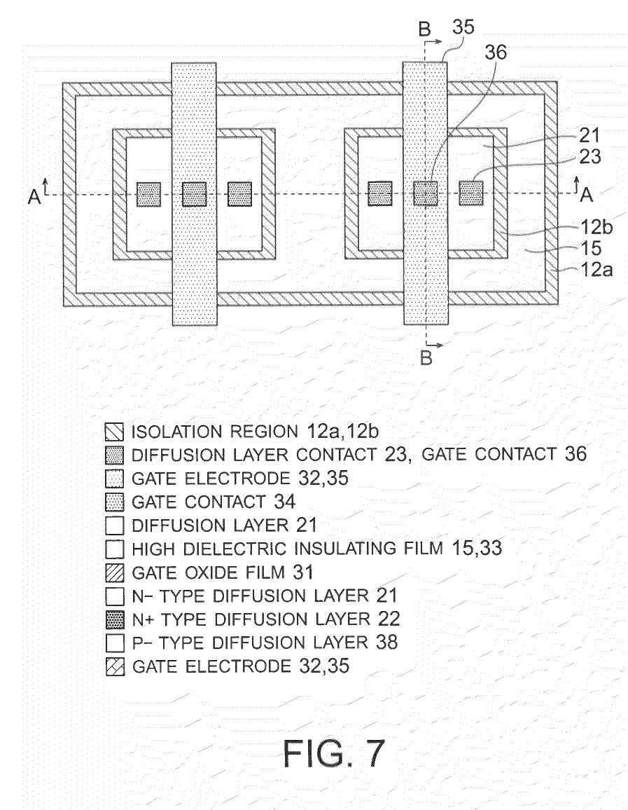

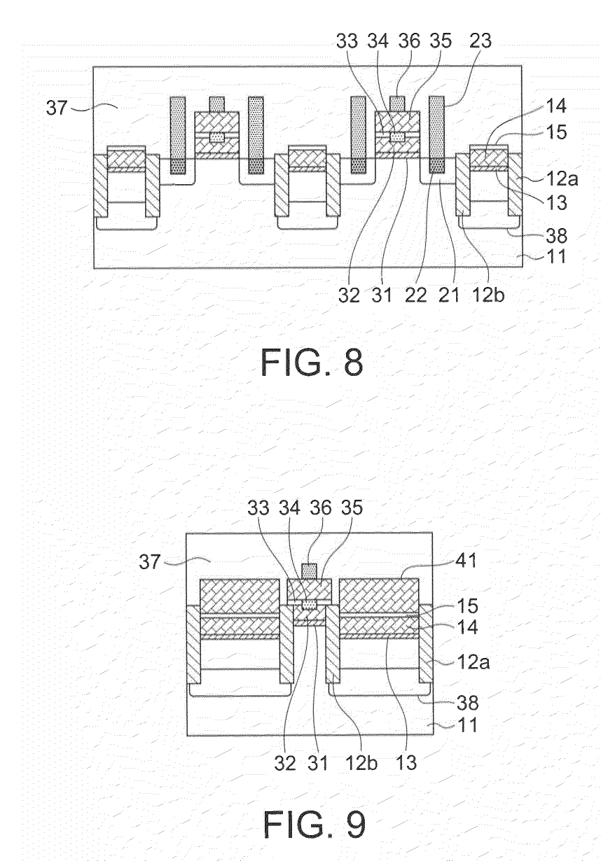

FIG. 7 shows a plan view of a structure of a group of high voltage MIS transistors in a semiconductor device of a second embodiment of the present invention. Further, FIGS. 8 and 9 show respective cross-sectional views taken along the lines A-A and B-B shown in FIG. 7. Note that the high voltage MIS transistor is a transistor driven by a high voltage of, e.g. 30 V, as a programming voltage in such a circuit as a row decoder circuit which is a part of the peripheral circuits of a non-volatile semiconductor memory device such as an NAND flash memory. In such MIS transistors, as described above, the impurity concentration of the channel region is required to be made lower than that of the low voltage MIS transistors.

As shown in FIGS. 7 and 8, two high voltage MIS transistors are disposed. A gate electrode 35 is provided in a vertical direction near the center of each of N⁻ type diffusion layers 21 and, a gate contact 36 is provided on the gate electrode 35. Source/drain diffusion layers are disposed on the left and right sides of the gate electrode 35 in the diffusion layer 21, and diffusion layer contacts 23 are provided on the respective surfaces thereof.

An isolation region 12b including a coating type insulating film composed of a polysilazane film and such embedded in an STI trench is formed on the circumference of the diffusion layer 21 of each of the MIS transistors so as to surround the diffusion layer 21. Further, a dummy element region is provided outside the isolation regions 12b for two pieces of the MIS transistors. A high dielectric film 15 is formed on the dummy element. Furthermore, an isolation region 12a is formed outside the dummy element regions of the MIS transistors so as to surround the dummy element regions. The isolation region 12a is formed by a coating type insulating film composed of a polysilazane film and such is embedded in an STI trench.

In FIG. 8, in a gate electrode region, a tunnel insulating film, i.e. a gate oxide film, 31 having a film thickness of, e.g. 15 to 40 nm; a floating gate electrode 32; an interelectrode insulating film 33 composed of a high dielectric insulating film and such; a control gate electrode 35; and a gate contact 34 provided in an opening formed in the interelectrode insulating film 33 are formed on the semiconductor substrate 11.

Further, the dummy element region is formed between the isolation regions 12b and 12a. The dummy element region includes an insulating film 13, a conductive film 14, and a high dielectric insulating film 15 are formed on the semiconductor substrate 11.

Note that, as the same as the first embodiment above, as long as the semiconductor substrate 11 lies in between the isolation regions 12b and 12a, it is not necessarily required for such films 13 to 15 to be formed. Likewise, in FIG. 9, although a conductive film 41 is formed on the insulating film 15 in the dummy element region, it is not necessarily required.

In the second embodiment, different from the first embodiment, a P⁻ type diffusion layer 38 is formed at a bottom portion in between the isolation regions 12b and 12a of the dummy element region. The P type impurity implanted in the diffusion layer 38 is, for example, the same conductive type as the semiconductor substrate 11. Consequently, even though the volume of the isolation region is reduced as the isolation region is divided by the isolation regions 12b and 12a and the isolation region is not entirely embedded with the insulating film, a leak current between adjacent transistors can be prevented from arising.

In the same manner as in the first embodiment above, the volume of the insulation film of the whole isolation regions as the STI trenches can be reduced by the isolation structured by dividing the isolation region into the isolation regions 12a and 12b with the dummy element region provided therebetween. Although polysilazane, for example, is used for the coating type insulating film in the STI trenches, the tensile stress is reduced by the reduced volume thereof. Consequently, the crystal defect of the semiconductor substrate 11 caused by the tensile stress is reduced, thereby preventing the circuit from malfunctioning.

In addition, reducing the volume of the coating type insulating film so as to reduce the influence of residual carbon can alleviate the action of negating the donor ions in the channel region of the high voltage MIS transistor where impurity concentration is low. Thereby, it is possible to prevent the influences of the variation in the threshold value Vth and such.

By preventing the threshold value Vth of the high voltage MIS transistor from varying, even when the width W of the transistor is formed smaller, the inverse narrow channel effect, which lowers the threshold value Vth, is reduced. Thus, the punch-through of the high voltage MIS transistor is prevented.

Meanwhile, when the distance between the high voltage MIS transistors decreases, the reverse field effect due to the coating type insulating film increases between a transistor in which a voltage is applied to the gate electrode and an adjacent transistor in which the voltage is not applied. Therefore, a leak current between the high-voltage MIS transistors may increase.

Now, a semiconductor device of a modification example of the second embodiment of the present invention will be described below. The plan view of the structure of this semiconductor device is the same as that of the abovementioned second embodiment shown in FIG. 7, thus its description is omitted.

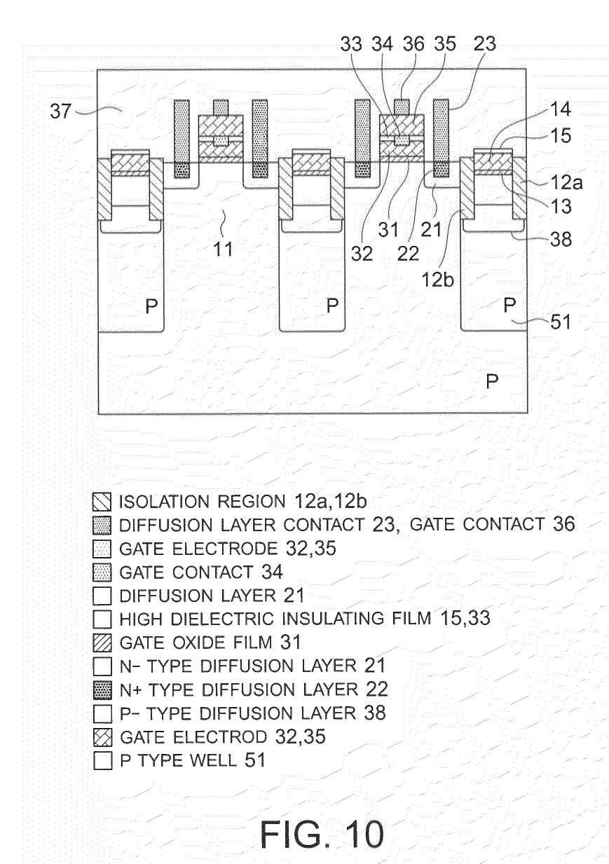

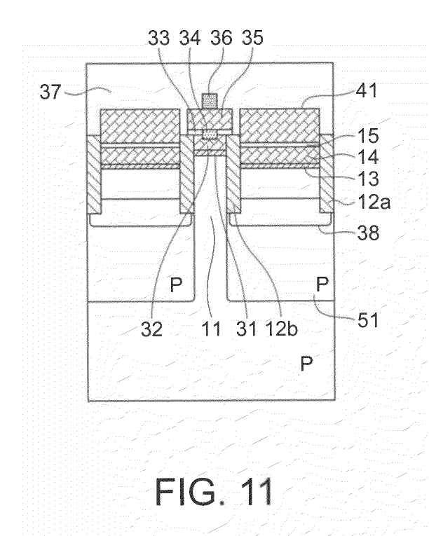

In this modification example, the cross-sectional structure differs from that of the second embodiment, thus FIGS. 10 and 11 show respective cross-sectional views taken along the lines A-A and B-B shown in FIG. 7. In the second embodiment described above, the P type diffusion layer 38 in the isolation region is in a floating state.

On the contrary, in the modification example, the P type diffusion layer 38 is electrically connected to a P type well 51. The P type well 51 is applied with ground potential. Consequently, the P type diffusion layer 38 becomes the same potential as the ground potential via the P type well 51, thus the drain leak and the punch-through leak between adjacent transistors can be prevented. As a result, the need for wide spacing between the high voltage MIS transistors is eliminated, thus the area of the semiconductor circuit can be reduced. Note that, in place of the P type well, the P type diffusion layer 38 may be connected to the semiconductor substrate where the ground potential is applied with.

As described above, the isolation of the cell array and the high voltage MIS transistors in the peripheral circuit can be fabricated at the same time by reducing the adverse effects to the high voltage MIS transistors in the peripheral circuit brought by the coating type insulating film used for fabricating fine cell arrays. Consequently, the number of fabricating steps is reduced, thereby achieving the cost reduction.

In the second embodiment, the isolation regions 12b are provided so as to surround each of the diffusion layers 21. The isolation region 12a is provided so as to surround the isolation regions 12b of the two MIS transistors which are adjacent to each other.

However, it is not necessarily required to define a unit with two MIS transistors as such. The isolation region 12a may be provided individually for each of the MIS transistors or may be provided so as to surround three or more of the MIS transistors.

### SECOND COMPARATIVE EXAMPLE

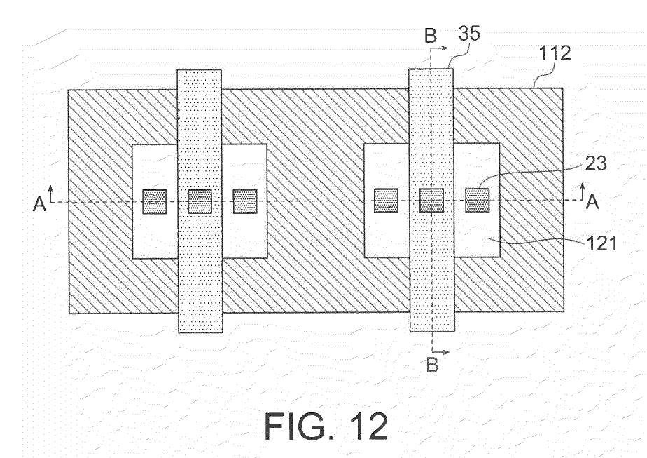

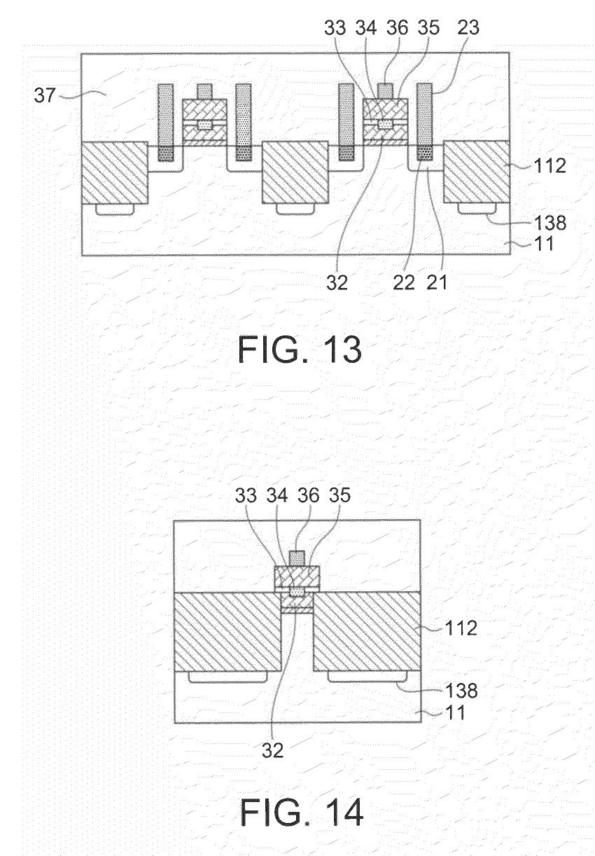

FIG. 12 shows a plan view of a structure of a group of low voltage MIS transistors in a semiconductor device of a second comparative example. Further, FIGS. 13 and 14 show respective cross-sectional views taken along the lines A-A and B-B shown in FIG. 12.

Different from the second embodiment described above, in the second comparative example, an isolation region 112 is provided as a single unit in an isolation region. The same constituent elements as those of the second embodiment are given with the same numerals, and their descriptions are omitted.

In the second comparative example, the entire STI trench is embedded with a coating type insulating film which constitutes the isolation region 112. Since its volume is larger than that of the second embodiment, the tensile stress by thermal shrinkage is more strongly exerted, thereby crystal defects are caused in the semiconductor substrate and lead the circuit to malfunction.

In addition, since the volume of the coating type insulation film is large and residual carbon has a stronger influence, the action of negating donor ions in the channel region appears, thereby bringing about the variations in the threshold value Vth. Further, when the width W of the transistor is formed smaller, the inverse narrow channel effect which lowers the threshold value Vth appears, thereby causing the punch-through.

Furthermore, since narrowing the distance between the high voltage MIS transistors increases the leak current as the reverse field effect is increased, the need to extend the distance between the transistors arises, thereby increasing the area of the circuit.

As described above, since the coating type insulating film for fabricating cell arrays brings about the adverse effects to the high voltage MIS transistors in the peripheral circuit, a need arises for the element isolation of the cell array and the high voltage MIS transistors in the peripheral circuit to be fabricated in separate steps, thereby increasing the cost.

### Third Embodiment

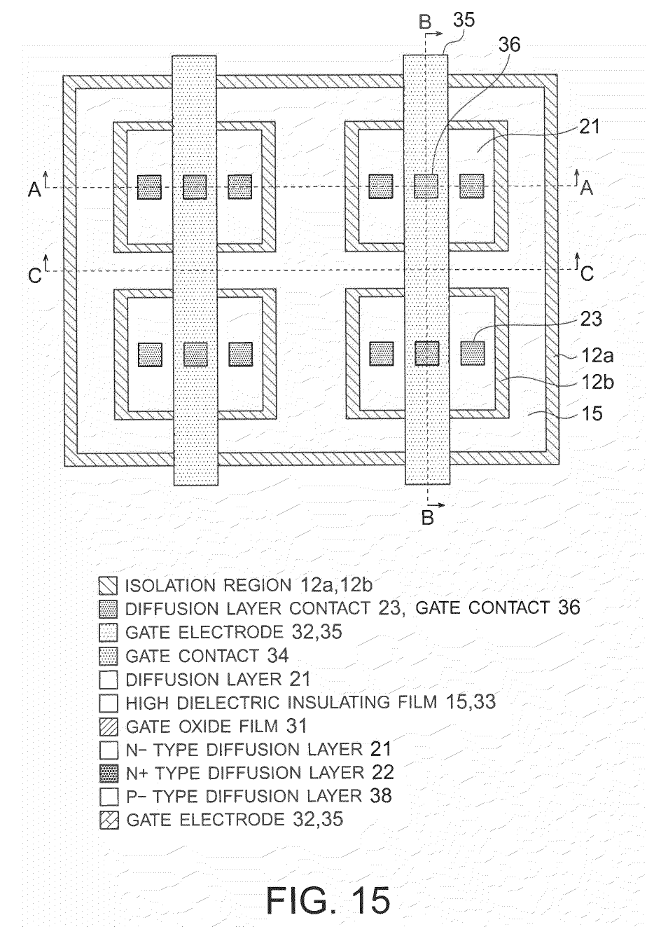

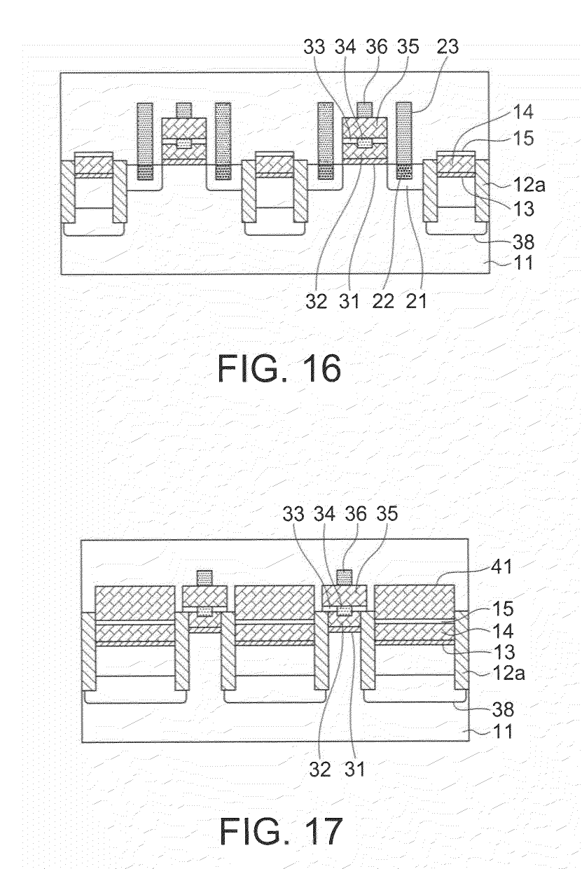

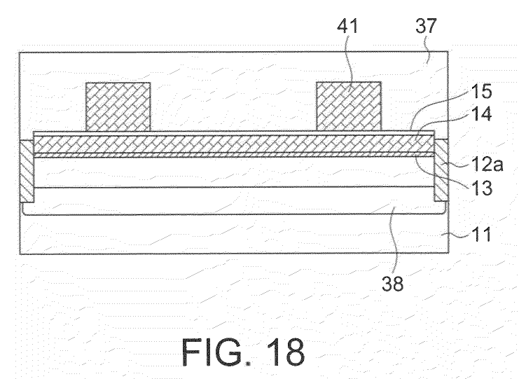

FIG. 15 shows a plan view of a structure of a group of high voltage MIS transistors included in a row decoder circuit of a semiconductor device of a third embodiment of the present invention. Further, FIGS. 16 to 18 show respective cross-sectional views taken along the lines A-A, B-B and C-C shown in FIG. 15. As the same as the second embodiment above, the impurity concentration of the channel region of the high voltage MIS transistor is required to be made lower than that of the low voltage MIS transistor.

As shown in FIGS. 15 and 16, four high voltage MIS transistors are disposed. A gate electrode 35 is provided in a vertical direction in each of N⁻ type diffusion layers 21 of the MIS transistors. A gate contact 36 is provided on the gate electrode 35. In the drawing, two pieces of MIS transistors disposed in the vertical direction have the gate electrode 35 continuously formed extending and connected with each other. Source/drain diffusion layers are disposed on the left and right sides of the gate electrode 35 in the diffusion layer 21. Diffusion layer contacts 23 are provided on the respective surfaces thereof.

An isolation region 12b is formed on the circumference of the diffusion layer 21 of each of the MIS transistors. The isolation region 12b is formed by a coating type insulating film composed of a polysilazane film and such embedded in an STI trench. Further, dummy element regions are formed outside the isolation regions 12b for four pieces of the MIS transistors. High dielectric films 15 are formed on the dummy element regions. Furthermore, an isolation region 12a is formed outside the dummy element regions of the MIS transistors so as to surround the dummy element regions. The isolation region 12a is formed by a coating type insulating film composed of a polysilazane film and such is embedded in an STI trench.

In FIG. 16, a tunnel insulating film, i.e. a gate oxide film, 31 having a film thickness of, e.g. 15 to 40 nm, on the semiconductor substrate 11; a floating gate electrode 32; an interelectrode insulating film 33 composed of a high dielectric insulating film and such; a control gate electrode 35; and a gate contact 34 provided in an opening formed in the interelectrode insulating film 33 are formed in a gate electrode region.

Further, an insulating film 13 and a conductive film 14 are formed on the semiconductor substrate 11 in the dummy element region between the isolation regions 12b and 12a described above. However, as long as the semiconductor substrate 11 lies in between the isolation regions 12b and 12a, it is not necessarily required for such films 13 to 15 to be formed. Further, a conductive film 41 formed on the high dielectric insulating film 15 in the dummy element region is not necessarily required either.

As shown in FIGS. 16 to 18, in the third embodiment, at a bottom portion in the dummy element region between the isolation regions 12b and 12a, a P⁻ type diffusion layer 38 is formed where a P type impurity of the same conductive type as the semiconductor substrate 11 is implanted. Consequently, even though the volume of the isolation region is reduced as the isolation region is divided by the isolation regions 12b and 12a and the isolation region is not entirely embedded with the insulating film, the leak current between adjacent transistors can be prevented from increasing.

As described in the second embodiment above, the P⁻ type diffusion layer 38 formed in the isolation region is electrically connected to and set at the same potential as the P type well or the P type semiconductor substrate 11. Thereby, an element isolation breakdown voltage is improved, and the drain leak and the punch-through leak between the adjacent transistors is prevented.

As the same as the first embodiment above, the element isolation is structured by dividing the element isolation insulating film into the isolation regions 12a and 12b with the dummy element region provided therebetween. Thereby, the volume of the insulating film of the whole isolation regions as the STI can be reduced. The tensile stress is reduced by reducing the volume of the coating type insulating film in the STI trenches. Thus the crystal defect of the semiconductor substrate 11 is prevented, and the circuit from malfunctioning is prevented.

In addition, such influences of the variation in the threshold value Vth can be prevented by reducing the volume of the coating type insulating film so as to reduce the influence of the residual carbon.

By the reduction of the variation in the threshold value Vth of the high voltage MIS transistor, even when the width W of the transistor is formed smaller, the inverse narrow channel effect which lowers the threshold value Vth is reduced. Thus, the punch-through of the high voltage MIS transistor is prevented.

Consequently, the need to extend the distance between high voltage MIS transistors is eliminated, thus the area of the semiconductor circuit can be reduced.

As described above, by reducing the adverse effects to the high voltage MIS transistors in the peripheral circuit brought by the coating type insulating film used for fabricating fine cell arrays, the element isolation of the cell array and the high voltage MIS transistors in the peripheral circuit can be fabricated at the same time. Consequently, the number of fabricating steps is reduced, thereby achieving the cost reduction.

In the third embodiment, the isolation region 12a is provided for the four MIS transistors so as to surround the isolation regions 12b which are provided so as to surround each of the diffusion layers 21.

However, it is not necessarily required to define a unit with four MIS transistors as such, and the isolation region 12a may be provided so as to surround three or less MIS transistors or may be provided so as to surround five or more MIS transistors.

### THIRD COMPARATIVE EXAMPLE

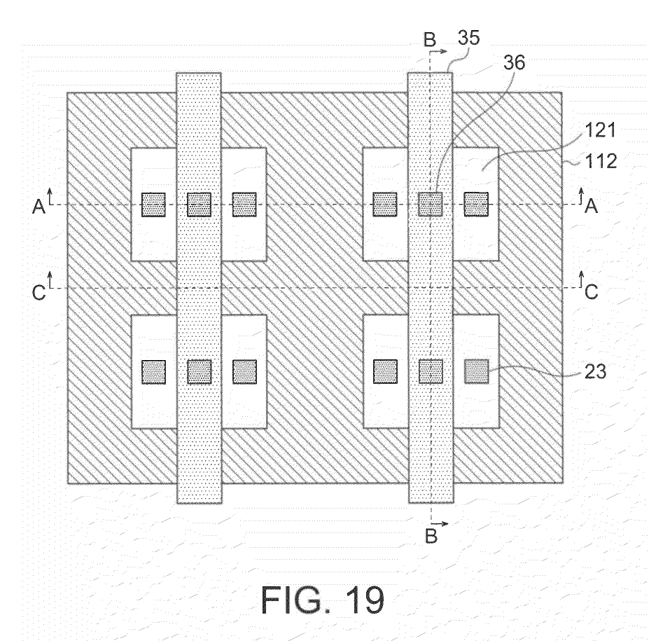

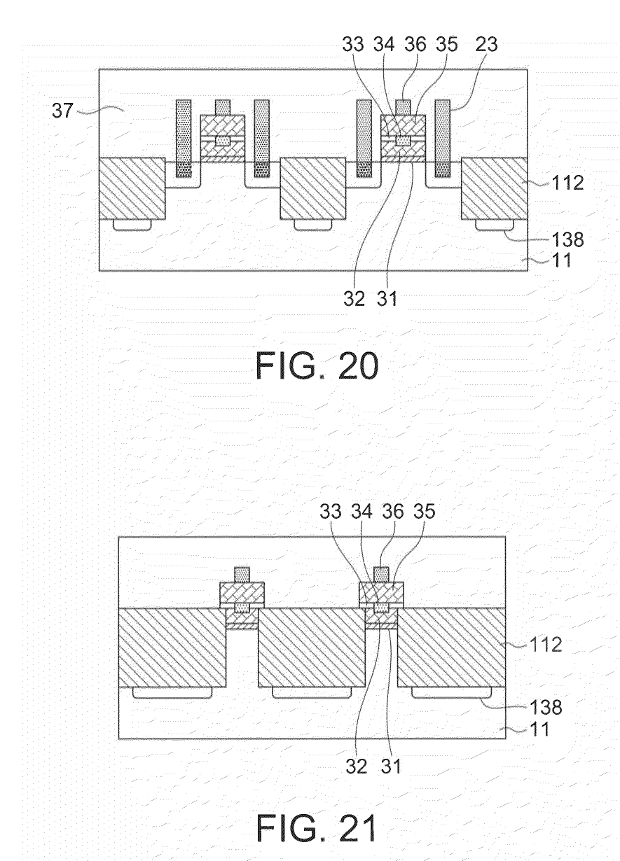

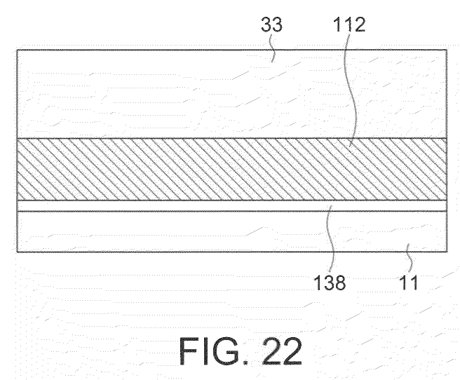

FIG. 19 shows a plan view of a structure of a group of high voltage MIS transistors included in a row decoder circuit of a semiconductor device of a third comparative example, while FIGS. 20 to 22 showing respective cross-sectional views taken along the lines A-A, B-B and C-C shown in FIG. 19.

Different from the third embodiment described above, in the third comparative example, an isolation region 112 is provided as a single unit in an isolation region. The same constituent elements as those of the third embodiment are given with the same numerals, and their descriptions are omitted.

In the third comparative example, since the entire STI trench is embedded with a coating type insulating film which constitutes the isolation region 112, its volume is larger than that of the third embodiment. Therefore, the tensile stress by thermal shrinkage is more strongly exerted. As a result, the crystal defect appears and causes the circuit to malfunction.

Since the volume of the coating type insulation film is large and residual carbon has a stronger influence, the action of negating donor ions in the channel region appears, thereby bringing about the variations in the threshold value Vth. Further, when the width of the transistor is formed smaller, the inverse narrow channel effect which lowers the threshold value Vth appears, thereby causing the punch-through.

Furthermore, since narrowing the distance between the high voltage MIS transistors increases the leak current as the reverse field effect is increased, the need to extend the distance between the transistors arises, thereby increasing the area of the circuit.

In order to eliminate such adverse effects to the high voltage MIS transistors in the peripheral circuit brought about by the coating type insulating film for fabricating cell arrays, a need arises for element isolation of the cell array and the high voltage MIS transistors in the peripheral circuit to be fabricated in separate steps, thereby increasing the cost.

Each of the embodiments of the present invention described above is only illustrative and various modifications and alterations may be made within the technical scope of the present invention. For example, the insulation material used for the isolation region is not limited to polysilazane and, as long as available as insulating films of coating type, other materials may be used.

Each of the embodiments of the present invention described above is only illustrative and various modifications and alterations may be made within the technical scope of the present invention.

1. A semiconductor device comprising:
a plurality of metal-insulator-semiconductor (MIS) transistors formed on a surface portion of a semiconductor substrate; and
an isolation region isolating each of element regions of the MIS transistors, the isolation region including a first isolation region formed with a coating type insulating film embedded in a first trench, the first trench surrounding each of the element regions of the MIS transistors, and a second isolation region formed with a coating type insulating film embedded in a second trench, the second trench surrounding at least one of the first isolation regions with a predetermined distance from each of the first isolation regions, wherein
the semiconductor substrate exists between the first isolation region and the second isolation region.

2. The semiconductor device according to claim 1, wherein the second isolation region surrounds the first isolation regions of at least two MIS transistors which are adjacent to each other.

3. The semiconductor device according to claim 1, wherein the second isolation region surrounds the first isolation regions of at least four MIS transistors which are disposed in an array.

4. The semiconductor device according to claim 1, further comprising:
an impurity diffusion layer of the same conductive type as the semiconductor substrate, the diffusion layer being provided at a bottom portion of the semiconductor substrate between the first isolation region and the second isolation region.

5. The semiconductor device according to claim 2, further comprising:
an impurity diffusion layer of the same conductive type as the semiconductor substrate, the diffusion layer being provided at a bottom portion of the semiconductor substrate between the first isolation region and the second isolation region.

6. The semiconductor device according to claim 3, further comprising:
an impurity diffusion layer of the same conductive type as the semiconductor substrate, the diffusion layer being provided at a bottom portion of the semiconductor substrate between the first isolation region and the second isolation region.

7. The semiconductor device according to claim 4, wherein the impurity diffusion layer is in a floating state which is a state electrically isolated from a well and the semiconductor substrate of the same conductive type, in which the MIS transistors are formed.

8. The semiconductor device according to claim 5, wherein the impurity diffusion layer is in a floating state which is a state electrically isolated from a well and the semiconductor substrate of the same conductive type, in which the MIS transistors are formed.

9. The semiconductor device according to claim 6, wherein the impurity diffusion layer is in a floating state which is a state electrically isolated from a well and the semiconductor substrate of the same conductive type, the MIS transistors are formed on the well or the semiconductor substrate.

10. The semiconductor device according to claim 4, wherein the impurity diffusion layer is electrically connected to a well or the semiconductor substrate of the same conductive type, the MIS transistors are formed on the well or the semiconductor substrate.

11. The semiconductor device according to claim 5, wherein the impurity diffusion layer is electrically connected to a well or the semiconductor substrate of the same conductive type, the MIS transistors are formed on the well or the semiconductor substrate.

12. The semiconductor device according to claim 6, wherein the impurity diffusion layer is electrically connected to a well or the semiconductor substrate of the same conductive type, the MIS transistors are formed on the well or the semiconductor substrate.

13. The semiconductor device according to claim 1, wherein the coating type insulating film involves a tensile stress.

14. The semiconductor device according to claim 2, wherein the coating type insulating film involves a tensile stress.

15. The semiconductor device according to claim 3, wherein the coating type insulating film involves a tensile stress.

16. The semiconductor device according to claim 4, wherein the coating type insulating film involves a tensile stress.

17. The semiconductor device according to claim 4, wherein a potential of the diffusion layer is applied with a ground potential.

18. The semiconductor device according to claim 5, wherein a potential of the diffusion layer is applied with a ground potential.

19. The semiconductor device according to claim 6, wherein a potential of the diffusion layer is applied with a ground potential.

20. The semiconductor device according to claim 1, wherein the coating type insulating film is formed by polysilazane.
